(19) United States
(12) Patent Application Publication
(10) Pub. No.: US 2024/0364050 A1
(43) Pub. Date: Oct. 31, 2024

(54) TEST CONNECTOR

(71) Applicant: okins electronics Co.,Ltd, Uiwang-si (KR)

(72) Inventors: Jin Kook JUN, Gunpo-si (KR); Chan Ho Lee, Siheung-si (KR); Seung Hyun NOH, Sacheon-si (KR)

(73) Assignee: okins electronics Co.,Ltd, Uiwang-si (KR)

(21) Appl. No.: 18/645,432

(22) Filed: Apr. 25, 2024

(30) Foreign Application Priority Data
Apr. 27, 2023 (KR) 10-2023-0055257

(51) Int. Cl. H01R 13/629; H01R 12/72; H01R 13/04

(52) U.S. Cl. CPC H01R 13/629; H01R 12/727; H01R 13/04

(57) ABSTRACT

A test connector tests the electrical characteristics of a semiconductor device, the test connector including a housing; a plurality of wafers having a plurality of coupling parts arranged at regular intervals on one side and stacked standing upright on the housing; a guide part having a width smaller than that of the plurality of coupling parts and arranged on one surface of the plurality of coupling parts; connector pins provided on both sides of the guide part, wherein the guide part includes a first introduction portion and a second introduction portion inclined in the center direction on both sides of an end thereof and the positions of the first introduction portion and the second introduction portion are different.

### CROSS-REFERENCE TO RELATED APPLICATION

This application claims priority to and the benefit of Korean Patent Application No. 10-2023-0055257, filed on Apr. 27, 2023, the entire contents of which is incorporated herein by reference.

### TECHNICAL FIELD

The present invention relates to a test connector for testing the electrical characteristics of semiconductor devices.

### BACKGROUND

In general, semiconductor devices are manufactured by integrating electronic circuits at high density on a circuit board, and after the semiconductor device is manufactured, it goes through an inspection process to check whether the semiconductor device operates properly before assembling it into a product.

A test connector is a device for testing the electrical characteristics of a semiconductor device and includes a first connector and a second connector.

The first connector and the second connector are configured to be coupled to each other, the first connector is connected to a system board, and the second connector is connected to a test board.

Here, the test board may be equipped with a test socket for mounting a plurality of semiconductor devices to be inspected.

The first connector is configured in a state in which a plurality of wafers equipped with a plurality of first connector pins are stacked standing upright upon a housing, and the second connector is configured in a state in which a plurality of wafers equipped with a plurality of second connector pins are stacked standing upright upon a housing.

The test connector is coupled with the first connector pin of the first connector and the second connector pin of the second connector facing each other.

In this way, when the first connector and the second connector are coupled, the first connector pin and the second connector pin are electrically connected. Accordingly, the system board and the test board are electrically connected so that the electrical characteristics of a plurality of semiconductor devices mounted on the test board can be inspected.

Meanwhile, in order to reliably electrically contact the first connector and the second connector, the second connector pin needs to press the first connector pin. To this end, the second connector pin uses elastic force to press the first connector pin.

However, due to this elastic force, when the first connector and the second connector are provided with a plurality of connector pins, there is a problem that a very high insertion force is required to couple the first connector and the second connector.

### SUMMARY

An object of the present invention is to provide a test connector that can easily couple a first connector and a second connector by minimizing the initial insertion force required to couple the first connector and the second connector.

The technical problems to be achieved in the present invention are not limited to the technical problems mentioned above, and other technical problems not mentioned will be clearly understood by those of ordinary skill in the art from the following description.

To achieve the above described objects, the present invention provides a test connector for testing the electrical characteristics of a semiconductor device, the test connector including a housing; a plurality of wafers having a plurality of coupling parts arranged at regular intervals on one side and stacked standing upright on the housing; a guide part having a width smaller than that of the plurality of coupling parts and arranged on one surface of the plurality of coupling parts; connector pins provided on both sides of the guide part, wherein the guide part includes a first introduction portion and a second introduction portion inclined in the center direction on both sides of an end thereof and the positions of the first introduction portion and the second introduction portion are different.

Here, the guide part further includes a flat portion at a position facing the first introduction portion, and the second introduction portion extends from the flat portion toward the connector pin.

In addition, the plurality of wafers have groove portions between the plurality of coupling parts.

In addition, the present invention provides a test connector for testing the electrical characteristics of a semiconductor device, the test connector including a housing; a plurality of wafers having a plurality of coupling parts arranged at regular intervals on one side and stacked standing upright on the housing; and connector pins provided on both sides of the plurality of coupling parts, wherein the connector pin includes a first connector pin and a second connector pin having different end positions.

In addition, the plurality of wafers include a first wafer having the first connector pin and a second wafer having the second connector pin.

In addition, in the plurality of wafers, the first wafer and the second wafer are stacked alternately.

In addition, the coupling part has introduction portions inclined in the center direction on both sides of an end thereof.

In addition, the plurality of wafers have groove portions between the plurality of coupling parts.

In addition, the connector pin has a bent portion bent toward the inside of the groove portion at an end thereof.

In addition, the present invention provides a test connector for testing the electrical characteristics of a semiconductor device, the test connector including a first connector; and a second connector coupled to the first connector, wherein the first connector includes a first housing; a plurality of first wafers having a plurality of first coupling parts arranged at regular intervals on one side and stacked standing upright on the first housing; a guide part having a width smaller than that of the plurality of first coupling parts and arranged on one surface of the plurality of first coupling parts; first connector pins provided on both sides of the guide part, wherein the guide part includes a first introduction portion and a second introduction portion inclined in the center direction on both sides of an end thereof and the positions of the first introduction portion and the second introduction portion are different, and wherein the second connector includes a second housing; a plurality of second wafers having a plurality of second coupling parts arranged at regular intervals on one side and stacked standing upright on the second housing; and second connector pins provided on both sides of the plurality of second coupling parts.

Here, the second connector pin includes a third connector pin and a fourth connector pin having different end positions.

In addition, the guide part further includes a flat portion at a position facing the first introduction portion, and the second introduction portion extends from the flat portion toward the first connector pin.

In addition, the plurality of second wafers include a third wafer having the third connector pin and a fourth wafer having the fourth connector pin.

In addition, in the plurality of second wafers, the third wafer and the fourth wafer are stacked alternately.

In addition, the second coupling part has third introduction portions inclined in the center direction on both sides of an end thereof.

In addition, the plurality of second wafers have groove portions between the plurality of coupling parts.

In addition, the second connector pin has a bent portion bent toward the inside of the groove portion at an end thereof.

According to the present invention, by adopting a configuration in which the initial insertion force required to couple the first connector and the second connector is divided and applied step by step, thereby minimizing the initial insertion force, it is possible to easily couple the first connector and the second connector.

The effects of the present invention are not limited to those mentioned above, and other effects not mentioned will be clearly understood by those of ordinary skill in the art from the following description.

### BRIEF DESCRIPTION OF THE DRAWINGS

FIG. 1 is a perspective view showing a test connector according to an embodiment of the present invention, where first and second connectors are coupled.

FIG. 2 is a perspective view showing a test connector according to an embodiment of the present invention, where first and second connectors are decoupled.

FIG. 3 is a side cross-sectional view showing a test connector according to an embodiment of the present invention, where first and second connectors are coupled.

FIG. 4 is an exploded perspective view of a first connector according to an embodiment of the present invention.

FIG. 5 is an exploded perspective view of a second connector according to an embodiment of the present invention.

FIG. 6 is a view showing the outside of a first wafer of the first connector according to an embodiment of the present invention.

FIG. 7 is a view showing the inside of the first wafer of the first connector according to an embodiment of the present invention.

FIG. 8 is a view showing the outside of a second wafer of the second connector according to an embodiment of the present invention.

FIG. 9 is a view showing the inside of the second wafer of the second connector according to an embodiment of the present invention.

FIG. 10 is a view showing a process of coupling the first connector and the second connector according to an embodiment of the present invention.

FIG. 11 is a view showing a third wafer and a fourth wafer according to an embodiment of the present invention.

FIG. 12 is an enlarged view of the third wafer and the fourth wafer shown in FIG. 11.

FIG. 13 is a view for describing a process in which the third wafer and the fourth wafer shown in FIG. 11 are coupled with the first wafer.

### DETAILED DESCRIPTION OF THE EMBODIMENTS

Preferred embodiments according to the present invention will be described in detail with reference to the accompanying drawings, but the same or similar components are assigned the same reference numerals regardless of the drawing numerals, and redundant description thereof will be omitted.

In addition, in describing the present invention, when it is determined that a detailed description of a related known technology may obscure the subject matter of the present invention, the detailed description will be omitted. In addition, it should be noted that the accompanying drawings are only intended to facilitate easy understanding of the idea of the present invention, and should not be construed as limiting the idea of the present invention by the accompanying drawings.

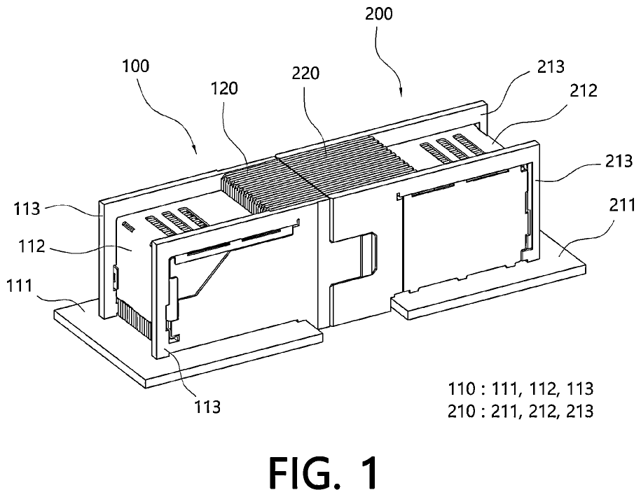

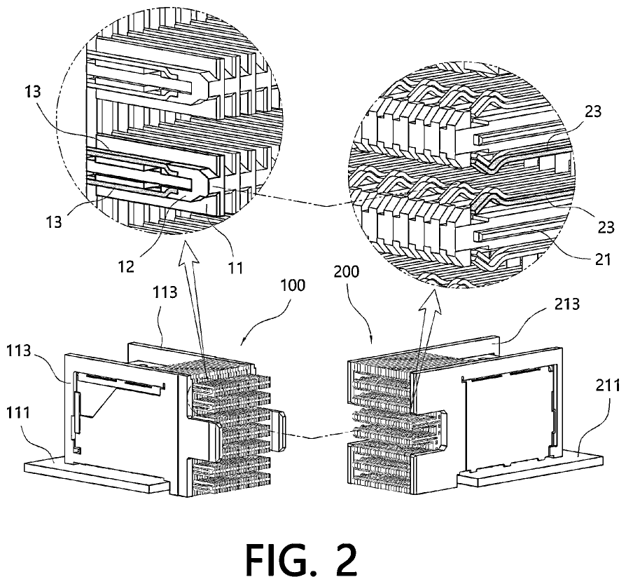

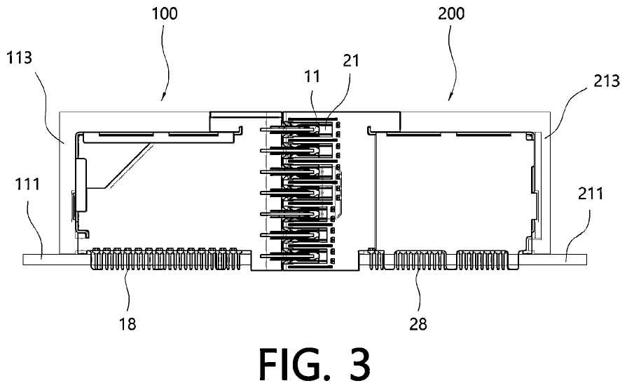

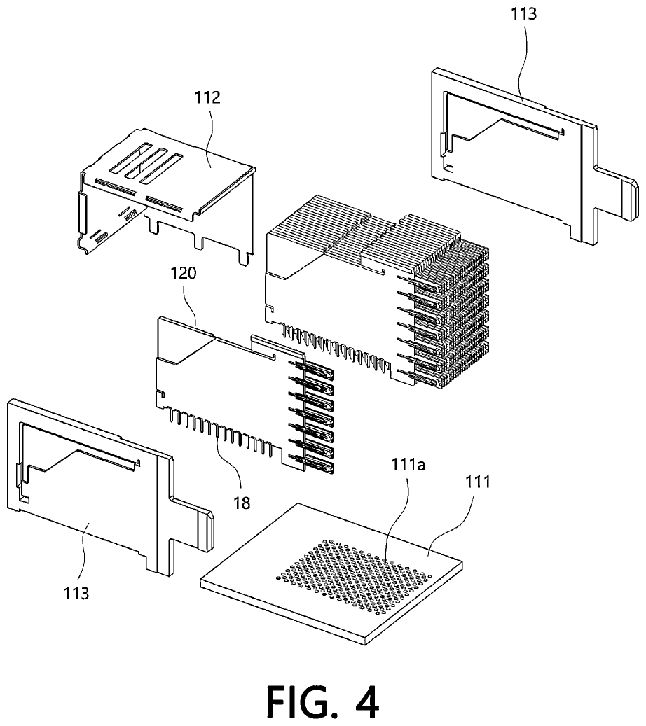

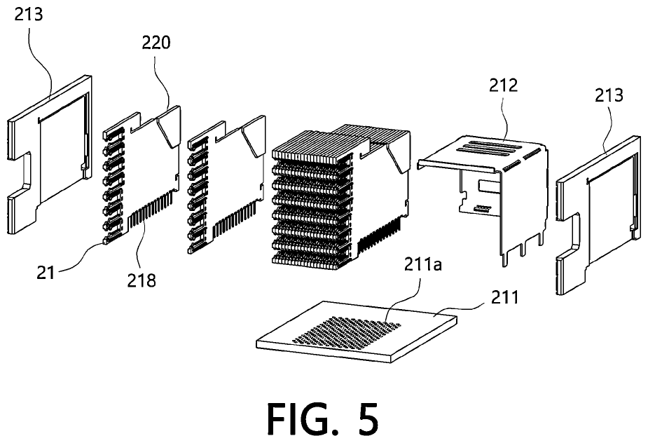

FIG. 1 is a perspective view showing a test connector according to an embodiment of the present invention, where first and second connectors are coupled, FIG. 2 is a perspective view showing a test connector according to an embodiment of the present invention, where first and second connectors are decoupled, FIG. 3 is a side cross-sectional view showing a test connector according to an embodiment of the present invention, where first and second connectors are coupled, FIG. 4 is an exploded perspective view of a first connector according to an embodiment of the present invention, and FIG. 5 is an exploded perspective view of a second connector according to an embodiment of the present invention.

Hereinafter, a test connector according to an embodiment of the present invention will be described with reference to FIGS. 1 to 5.

The test connector according to an embodiment of the present invention is a device for testing the electrical characteristics of a semiconductor device and may include a first connector 100 and a second connector 200.

The first connector 100 and the second connector 200 are configured to be coupled to each other, and the first connector 100 may be connected to a test board and the second connector 200 may be connected to a system board. On the contrary, the first connector 100 may be connected to a system board, and the second connector 200 may be connected to a test board.

Here, the test board may be equipped with a test socket for mounting a plurality of semiconductor devices to be inspected.

The first connector 100 may include a first housing 110 and a plurality of first wafers 120.

The plurality of first wafers 120 may be stacked standing upright on the first housing 110.

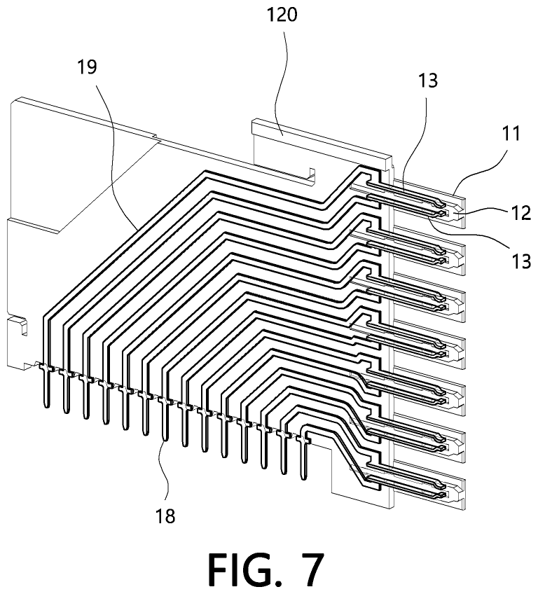

The plurality of first wafers 120 may include a plurality of first coupling parts 11, guide parts 12, first connector pins 13, connection terminals 18, and wirings (19 in FIG. 7).

The plurality of first coupling parts 11 are arranged at regular intervals on one side of the first wafer 120, and groove portions may be provided between the plurality of first coupling parts 11. Here, the plurality of first coupling parts 11 are provided in a form extending to a certain length from one side of the first wafer 120, and one side of the first wafer 120 refers to a portion coupled to the second connector 200.

In addition, the plurality of connection terminals 18 connected to a test board or system board are provided on the lower side of the plurality of first wafers 120.

The guide part 12 has a width smaller than that of the plurality of first coupling parts 11 and is arranged on one surface of the plurality of first coupling parts 11.

The first connector pin 13 may be provided on both sides of the guide part 12 in a fixed state.

The first connector pin 13 and the connection terminal 18 may be provided in a form connected by a wiring (19 in FIG. 7). Here, the first connector pin 13 is exposed on one side of the first wafer 120, and the connection terminal 18 is exposed on the lower side of the first wafer 120. However, the wiring (19 in FIG. 7) may be provided inside the first wafer 120.

The first housing 110 may include a base 111, an upper cover 112, and a side cover 113. Here, the base 111, the upper cover 112, and the side cover 113 may be separately configured and assembled to provide a plurality of first wafers 120 inside the first housing 110, but are not limited thereto.

A plurality of through holes 111a are formed in the base 111 to correspond to a plurality of connection terminals 18 of the first wafer 120. When a plurality of first wafers 120 are provided in the first housing 110, the plurality of connection terminals 18 may be exposed to the outside from the plurality of through holes 111a. Accordingly, a plurality of connection terminals 18 may be connected to a connection pad of the system board or the test board.

The second connector 200 may include a second housing 210 and a plurality of second wafers 220.

The plurality of second wafers 220 may be stacked standing upright on the second housing 210.

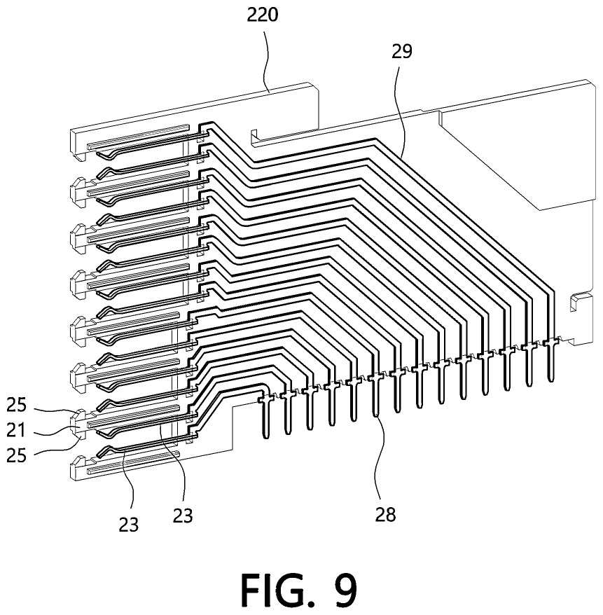

The plurality of second wafers 220 may include a plurality of second coupling parts 21, second connector pins 23, connection terminals 28, and wirings (29 in FIG. 9).

The plurality of second coupling parts 21 are arranged at regular intervals on one side of the second wafer 220, and groove portions may be provided between the plurality of second coupling parts 21. Here, the plurality of second coupling parts 21 are provided in a form extending to a certain length from one side of the second wafer 220, and one side of the second wafer 220 refers to a portion coupled to the first connector 100.

In addition, the plurality of connection terminals 28 connected to a test board or system board are provided on the lower side of the plurality of second wafers 220.

The second connector pin 23 may be provided on both sides of the second coupling part 21 in an elastically deformable state.

The second connector pin 23 and the connection terminal 28 may be provided in a form connected by a wiring (29 in FIG. 9). Here, the second connector pin 23 is exposed on one side of the second wafer 220, and the connection terminal 28 is exposed on the lower side of the second wafer 220. However, the wiring (29 in FIG. 9) may be provided inside the second wafer 220.

The second housing 210 may include a base 211, an upper cover 212, and a side cover 213. Here, the base 211, the upper cover 212, and the side cover 213 may be separately configured and assembled to provide a plurality of second wafers 220 inside the second housing 210, but are not limited thereto.

A plurality of through holes 211a are formed in the base 211 to correspond to a plurality of connection terminals 28 of the second wafer 220. When a plurality of second wafers 220 are provided in the second housing 210, the plurality of connection terminals 28 may be exposed to the outside from the plurality of through holes 211a. Accordingly, a plurality of connection terminals 28 may be connected to a connection pad of the system board or the test board.

The test connector according to an embodiment of the present invention is coupled with the first connector pin 13 of the first connector 100 and the second connector pin 23 of the second connector 200 facing each other. Here, the first coupling part 11 of the first connector 100 is inserted into the groove portion of the second connector 200, and the second coupling part 21 of the second connector 100 is inserted into the groove portion of the first connector 100, so that the first connector 100 and the second connector 200 may be coupled.

In this way, when the first connector 100 and the second connector are coupled, the first connector pin 13 and the second connector pin 23 may be electrically connected. Accordingly, the system board and the test board are electrically connected so that the electrical characteristics of a plurality of semiconductor devices mounted on the test board can be inspected.

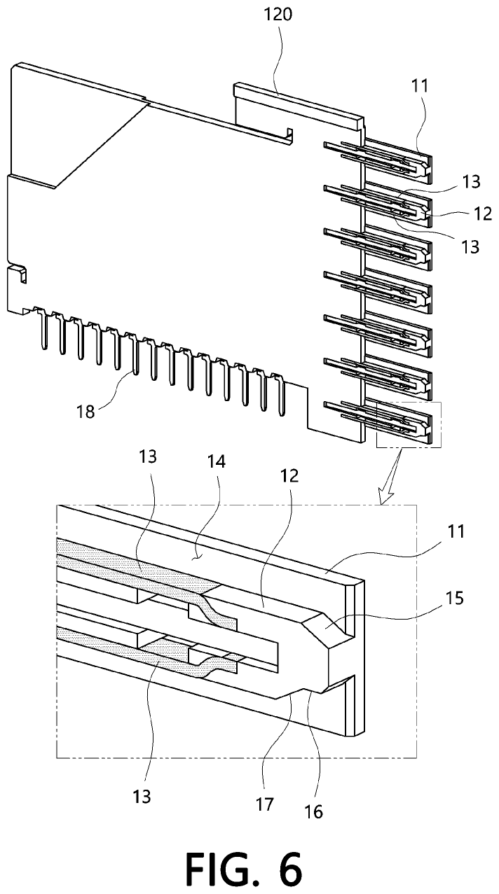

FIG. 6 is a view showing the outside of a first wafer of the first connector according to an embodiment of the present invention, and FIG. 7 is a view showing the inside of the first wafer of the first connector according to an embodiment of the present invention.

Referring to FIGS. 6 and 7, the first wafer 120 may include a plurality of first coupling parts 11, guide parts 12, first connector pins 13, connection terminals 18, and wirings 19.

The plurality of first coupling parts 11 are arranged at regular intervals on one side of the first wafer 120, and groove portions may be provided between the plurality of first coupling parts 11. Here, the plurality of first coupling parts 11 are provided in a form extending to a certain length from one side of the first wafer 120, and one side of the first wafer 120 refers to a portion coupled to the second connector 200.

In addition, the plurality of connection terminals 18 connected to a test board or system board are provided on the lower side of the plurality of first wafers 120.

The guide part 12 has a width smaller than that of the plurality of first coupling parts 11 and is arranged on one surface of the plurality of first coupling parts 11. Here, since the guide part 12 is arranged at the center of the plurality of first coupling parts 11 and has a width smaller than that of the plurality of first coupling parts 11, a guide space 14 is formed on both sides of the guide part 12 to guide the movement of the second connector pin 23 of the second connector 200.

The first connector pin 13 may be provided on both side surfaces of the guide part 12 in a fixed state. Here, when the second connector pin 23 of the second connector 200 moves along the guide space 14 and the coupling of the first connector 100 and the second connector 200 is completed, the second connector pin 23 may be electrically connected to the first connector pin 13.

The first connector pin 13 and the connection terminal 18 may be provided in a form connected by the wiring 19. Here, the first connector pin 13 is exposed on one side of the first wafer 120, and the connection terminal 18 is exposed on the lower side of the first wafer 120. However, the wiring 19 may be provided inside the first wafer 120.

The guide part 12 has a first introduction portion 15 and a second introduction portion 17 inclined in the center direction on both sides of an end thereof. Here, the first introduction portion 15 and the second introduction portion 17 are characterized in that positions thereof are different from each other. This will be described in detail later.

The guide part 12 has a flat portion 16 at a position facing the first introduction portion 15, and the second introduction portion 17 extends from the flat portion 16 toward the first connector pin 13.

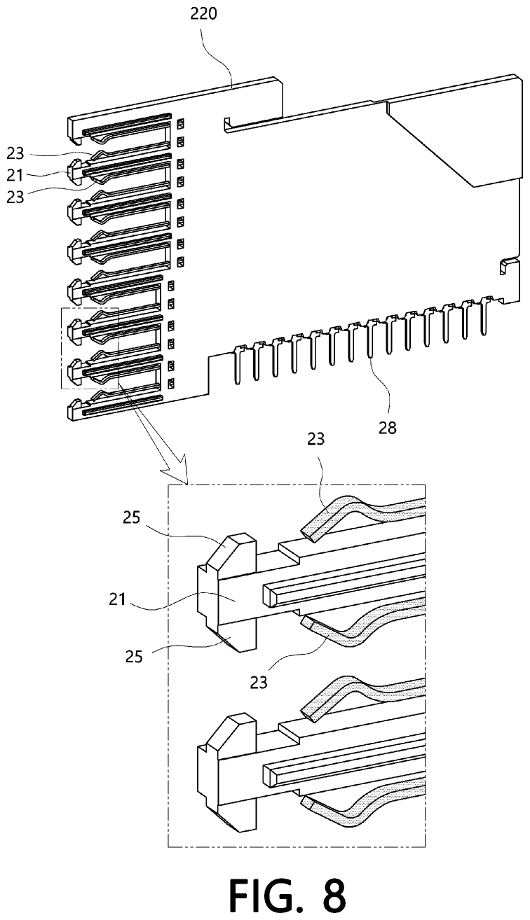

FIG. 8 is a view showing the outside of a second wafer of the second connector according to an embodiment of the present invention, and FIG. 9 is a view showing the inside of the second wafer of the second connector according to an embodiment of the present invention.

Referring to FIGS. 8 and 9, the plurality of second wafers 220 may include a plurality of second coupling parts 21, second connector pins 23, connection terminals 28, and wirings 29.

The plurality of second coupling parts 21 are arranged at regular intervals on one side of the second wafer 220, and groove portions may be provided between the plurality of second coupling parts 21. Here, the plurality of second coupling parts 21 are provided in a form extending to a certain length from one side of the second wafer 220, and one side of the second wafer 220 refers to a portion coupled to the first connector 100.

The plurality of second coupling parts 21 have third introduction portions 25 inclined in the center direction on both sides of an end thereof.

In addition, the plurality of connection terminals 28 connected to a test board or system board are provided on the lower side of the plurality of second wafers 220.

The second connector pin 23 may be provided on both sides of the second coupling part 21 in an elastically deformable state.

The second connector pin 23 has a bent portion bent toward the inside of the groove portion at an end thereof.

The second connector pin 23 and the connection terminal 28 may be provided in a form connected by the wiring 29. Here, the second connector pin 23 is exposed on one side of the second wafer 220, and the connection terminal 28 is exposed on the lower side of the second wafer 220. However, the wiring 29 may be provided inside the second wafer 220.

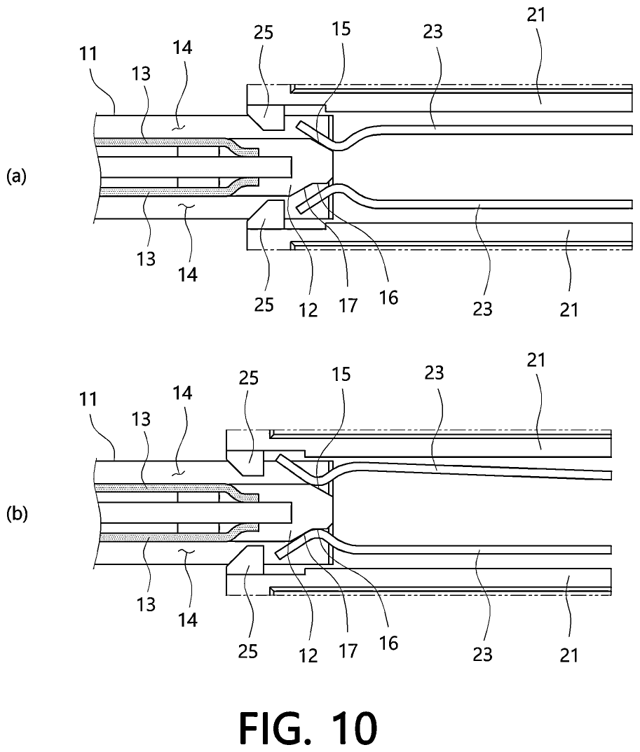

FIG. 10 is a view showing a process of coupling the first connector and the second connector according to an embodiment of the present invention.

Referring to FIG. 10, the test connector according to an embodiment of the present invention is coupled with the first connector pin 13 of the first connector 100 and the second connector pin 23 of the second connector 200 facing each other. Here, the first coupling part 11 of the first connector 100 is inserted into the groove portion of the second connector 200, and the second coupling part 21 of the second connector 100 is inserted into the groove portion of the first connector 100, so that the first connector 100 and the second connector 200 may be coupled.

Specifically, when the first coupling part 11 of the first connector 100 is inserted into the groove portion of the second connector 200 and then pressed, the third introduction portion 25 provided on both sides of the groove portion end of the second connector 200 moves along the guide space 14.

Second connector pins 23 are provided to face each other on the upper and lower sides of the groove portion of the second connector 200. Here, the ends of the second connector pins 23 provided on the upper and lower sides of the groove portion are provided with bent portions bent inside the groove portion of the second connector 200. Here, the positions of the bent portions of the second connector pins 23 provided on the upper and lower sides of the groove portion are the same.

As described above, the test connector according to an embodiment of the present invention is characterized in that the positions of the first introduction portion 15 and the second introduction portion 17 inclined in the center direction on both sides of an end of the guide part 12 are different. That is, the guide part 12 has a flat portion 16 at a position facing the first introduction portion 15, and the second introduction portion 17 extends from the flat portion 16 toward the first connector pin 13.

Accordingly, first, when the first coupling part 11 of the first connector 100 is inserted into the groove portion of the second connector 200, the third introduction portion 25 moves to the guide space 14. Here, since the third introduction portion 25 has a shape inclined toward the inside of the groove portion, it may be easily introduced into the guide space 14.

At this time, as shown in FIG. 10(a), the bent portion of the second connector pin 23 provided on the upper side of the groove portion is in contact with the first introduction portion 15 but since the bent portion of the second connector pin 23 provided on the lower side of the groove portion is located on the flat portion 16, the bent portion is not in contact with the second introduction portion 17.

In this state, when at least one of the first connector 100 and the second connector 200 is pressed in a direction being coupled to each other, as shown in FIG. 10 (b), the bent portion of the second connector pin 23 provided on the upper side of the groove portion moves along the first introduction portion 15 by elastic force to enter the guide space 14. Here, an initial insertion force is required to allow the bent portion of the second connector pin 23 provided on the upper side of the groove portion to enter the guide space 14. At this time, the bent portion of the second connector pin 23 provided on the lower side of the groove portion comes into contact with the second introduction portion 17.

In this state, when at least one of the first connector 100 and the second connector 200 is pressed in a direction being coupled to each other, the bent portion of the second connector pin 23 provided on the lower side of the groove portion moves along the second introduction portion 17 by elastic force to enter the guide space 14. Here, an initial insertion force is required to allow the bent portion of the second connector pin 23 provided on the lower side of the groove portion to enter the guide space 14.

After both the bent portions of the second connector pin 23 provided on the upper and lower sides of the groove portion enter the guide space 14, when at least one of the first connector 100 and the second connector 200 is pressed in a direction being coupled to each other, the second connector pin 23 moves and the bent portions of the second connector pin 23 provided on the upper and lower sides of the groove portion contact the first connector pin 13 provided on both sides of the guide part 12. In this case, the bent portions of the second connector pin 23 can be firmly contacted with the guide part 12 by elastic restoring force.

In this way, the test connector according to an embodiment of the present invention adopts a configuration in which the initial insertion force required for the bent portions of the second connector pin 23 provided on the upper and lower sides of the groove portion to enter the guide space 14 is divided and applied step by step, thereby minimizing the initial insertion force and easily coupling the first connector 100 and the second connector 200.

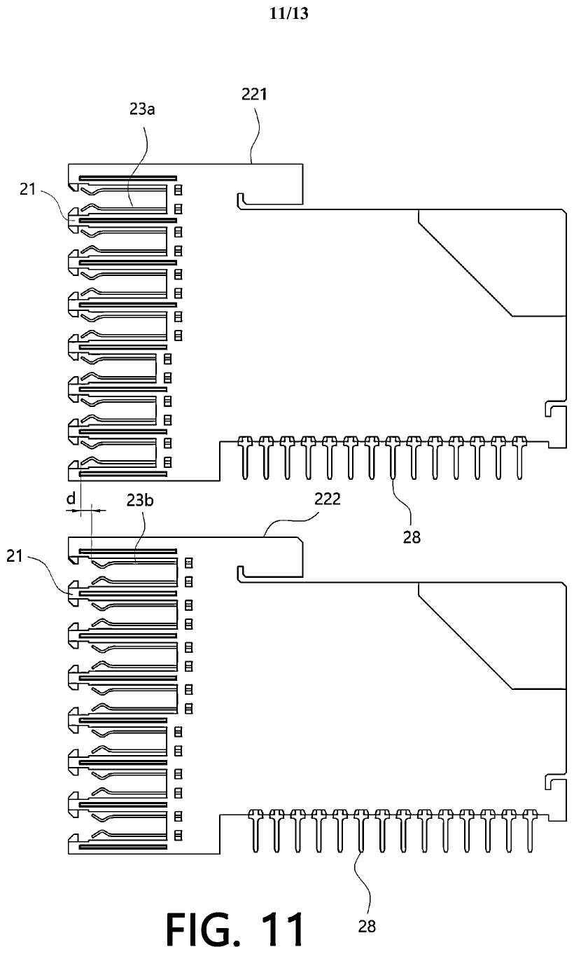

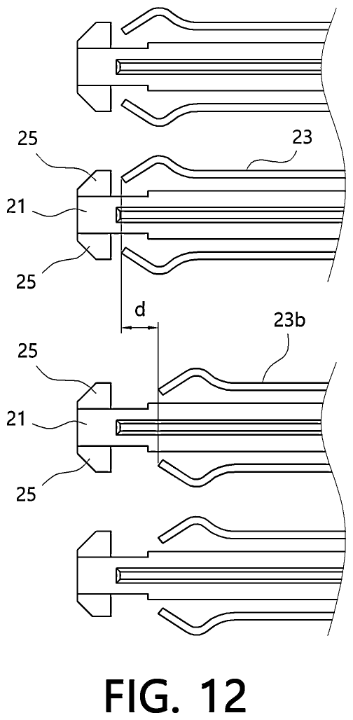

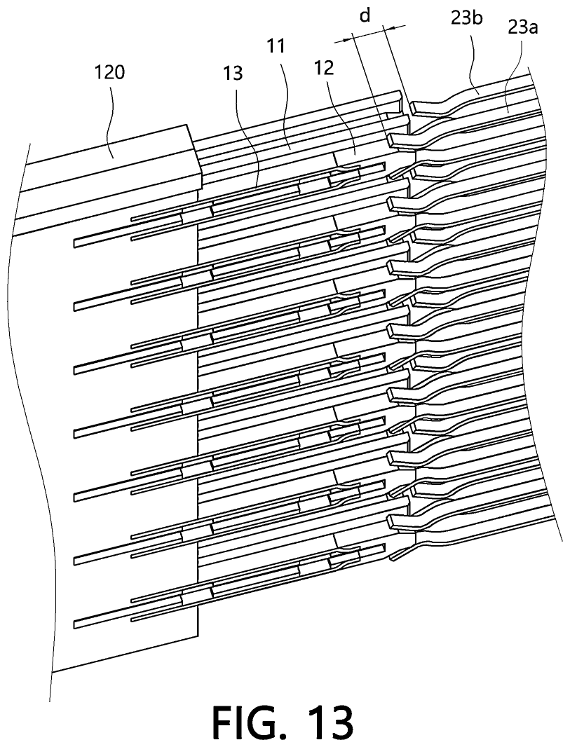

FIG. 11 is a view showing a third wafer and a fourth wafer according to an embodiment of the present invention, FIG. 12 is an enlarged view of the third wafer and the fourth wafer shown in FIG. 11, and FIG. 13 is a view for describing a process in which the third wafer and the fourth wafer shown in FIG. 11 are coupled with the first wafer.

Referring to FIGS. 11 and 12, the plurality of second wafers 220 of the second connector 200 include a third wafer 221 and a fourth wafer 222. Here, the plurality of second wafers 220 may be configured by alternately stacking third wafers 221 and fourth wafers 222.

The second connector pin 23 includes a third connector pin 23a and a fourth connector pin 23b having different end positions.

Here, the third wafer 221 includes the third connector pin 23a, and the fourth wafer 222 includes the fourth connector pin 23b.

Accordingly, a positional deviation d of the bent portion occurs in a state where the third connector pin 23a and the fourth connector pin 23b are provided on the third wafer 221 and the fourth wafer 222.

Due to the positional deviation d of the bent portion, when the first connector 100 and the second connector 200 are combined, the third connector pin 23a enters the guide space 14 and then the fourth connector pin 23b enters the guide space 14.

Specifically, referring to FIG. 13, when at least one of the first connector 100 and the second connector 200 is pressed in a direction being coupled to each other, the bent portion of the third connector pin 23a sequentially moves along the first introduction portion 15 and the second introduction portion 17 by elastic force to enter the guide space 14. Here, an initial insertion force is required to allow the bent portion of the third connector pin 23a to enter the guide space 14.

Thereafter, when at least one of the first connector 100 and the second connector 200 is pressed in a direction being coupled to each other, the bent portion of the fourth connector pin 23b sequentially moves along the first introduction portion 15 and the second introduction portion 17 by clastic force to enter the guide space 14. Here, an initial insertion force is required to allow the bent portion of the fourth connector pin 23b to enter the guide space 14.

After the bent portion of the fourth connector pin 23b enters the guide space 14, when at least one of the first connector 100 and the second connector 200 is pressed in a direction being coupled to each other, the third connector pin 23a and the fourth connector pin 23b move and the bent portions of the third connector pin 23a and the fourth connector pin 23b contact the first connector pin 13 provided on both sides of the guide part 12.

In this way, the test connector according to an embodiment of the present invention adopts a configuration in which the initial insertion force required for the third connector pin 23a and the fourth connector pin 23b provided on the alternately stacked third wafer 221 and fourth wafer 222 to enter the guide space 14 is divided and applied step by step, thereby minimizing the initial insertion force and easily coupling the first connector 100 and the second connector 200.

The embodiments described in the present specification and the accompanying drawings are merely illustrative of some of the technical ideas included in the present invention.

Accordingly, since the embodiments disclosed in the present specification are not intended to limit the technical idea of the present invention, but are for illustrative purposes, it is obvious that the scope of the technical idea of the present invention is not limited by these embodiments. Modifications and specific embodiments that can be easily inferred by those skilled in the art within the scope of the technical idea included in the specification and drawings of the present invention should be construed as being included in the scope of the present invention.

What is claimed is:

1. A test connector for testing electrical characteristics of a semiconductor device, the test connector comprising:
a housing;
a plurality of wafers having a plurality of coupling parts arranged at regular intervals on one side and stacked standing upright on the housing;
a guide part having a width smaller than that of the plurality of coupling parts and arranged on one surface of the plurality of coupling parts; and
connector pins provided on both sides of the guide part,
wherein the guide part comprises a first introduction portion and a second introduction portion inclined in the center direction on both sides of an end thereof and the positions of the first introduction portion and the second introduction portion are different.

2. The test connector according to claim 1,
wherein the guide part further comprises a flat portion at a position facing the first introduction portion, and
the second introduction portion extends from the flat portion toward the connector pin.

3. The test connector according to claim 1, wherein the plurality of wafers have groove portions between the plurality of coupling parts.

4. A test connector for testing the electrical characteristics of a semiconductor device, the test connector comprising:
a housing;
a plurality of wafers having a plurality of coupling parts arranged at regular intervals on one side and stacked standing upright on the housing; and
connector pins provided on both sides of the plurality of coupling parts,
wherein the connector pin comprises a first connector pin and a second connector pin having different end positions.

5. The test connector according to claim 4, wherein the plurality of wafers comprise a first wafer having the first connector pin and a second wafer having the second connector pin.

6. The test connector according to claim 5, wherein in the plurality of wafers, the first wafer and the second wafer are stacked alternately.

7. The test connector according to claim 4, wherein the coupling part has introduction portions inclined in the center direction on both sides of an end thereof.

8. The test connector according to claim 4, wherein the plurality of wafers have groove portions between the plurality of coupling parts.

9. The test connector according to claim 8, wherein the connector pin has a bent portion bent toward the inside of the groove portion at an end thereof.

10. A test connector for testing the electrical characteristics of a semiconductor device, the test connector comprising:
a first connector; and
a second connector coupled to the first connector,
wherein the first connector comprises:
a first housing;
a plurality of first wafers having a plurality of first coupling parts arranged at regular intervals on one side and stacked standing upright on the first housing;
a guide part having a width smaller than that of the plurality of first coupling parts and arranged on one surface of the plurality of first coupling parts; and
first connector pins provided on both sides of the guide part,
wherein the guide part comprises a first introduction portion and a second introduction portion inclined in the center direction on both sides of an end thereof and the positions of the first introduction portion and the second introduction portion are different, and
wherein the second connector comprises:
a second housing;
a plurality of second wafers having a plurality of second coupling parts arranged at regular intervals on one side and stacked standing upright on the second housing; and
second connector pins provided on both sides of the plurality of second coupling parts.

11. The test connector according to claim 10, wherein the second connector pin comprises a third connector pin and a fourth connector pin having different end positions.

12. The test connector according to claim 10,
wherein the guide part further comprises a flat portion at a position facing the first introduction portion, and
the second introduction portion extends from the flat portion toward the first connector pin.

13. The test connector according to claim 11, wherein the plurality of second wafers further comprises a third wafer having the third connector pin and a fourth wafer having the fourth connector pin.

14. The test connector according to claim 13, wherein in the plurality of second wafers, the third wafer and the fourth wafer are stacked alternately.

15. The test connector according to claim 12, wherein the second coupling part has third introduction portions inclined in the center direction on both sides of an end thereof.

16. The test connector according to claim 12, wherein the plurality of second wafers have groove portions between the plurality of coupling parts.

17. The test connector according to claim 16, wherein the second connector pin has a bent portion bent toward the inside of the groove portion at an end thereof.
